(19) United States
(12) Patent Application Publication
(10) Pub. No.: US 2013/0308274 A1
(43) Pub. Date: Nov. 21, 2013

(54) THERMAL SPREADER HAVING GRADUATED THERMAL EXPANSION PARAMETERS

(71) Applicants: Dylan Murdock, Allen, TX (US); Lawrence Giacoma, Plano, TX (US)

(72) Inventors: Dylan Murdock, Allen, TX (US); Lawrence Giacoma, Plano, TX (US)

(73) Assignee: TRIQUINT SEMICONDUCTOR, INC., Hillsboro, OR (US)

(21) Appl. No.: 13/476,948

(22) Filed: May 21, 2012

(51) Int. Cl. H05K 7/20; H01L 21/60

(52) U.S. Cl. 361/717; 438/122; 257/E21.506

(57) ABSTRACT

Embodiments of the present disclosure describe apparatuses, methods, and systems of an integrated circuit (IC) device. The IC device may include a thermal spreader having graduated thermal expansion parameters. In some embodiments, the thermal spreader may have a first layer with a first coefficient of thermal expansion (CTE) and a second layer with a second CTE that is greater than the first CTE. Other embodiments may be described and/or claimed.

### FIELD

Embodiments of the present disclosure generally relate to the field of integrated circuits, and more particularly, to a thermal spreader having graduated thermal expansion parameters to be used with integrated circuits.

### BACKGROUND

High power microelectronic packages dissipate large densities of thermal energy. The packages use metallic thermal spreaders for their base material and are frequently attached to a heat sink with screws. Attaching the metallic thermal spreaders to a heat sink with screws preloads the thermal spreader into the heat sink. When a plate is preloaded at two or more locations around its perimeter, a central deflection may result causing the thermal spreader to separate from heat sink at the desired point of contact. This deflection can leave an air gap that cuts off the thermal path in a very high heat flux area. This may result in high operating temperatures and increase a risk of product failures.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIGS. 1(a) and (b) respectively illustrate a cross-section perspective view and side view of an integrated circuit (IC) device according to various embodiments.

FIGS. 2(a) and (b) respectively illustrate a cross-section perspective view and side view of an IC device according to various embodiments.

FIG. 3 is a flow diagram of a method for fabricating an IC device according to various embodiments.

FIG. 4 illustrates an example system including an IC device according to various embodiments.

### DETAILED DESCRIPTION

Embodiments of the present disclosure provide a thermal spreader having graduated thermal expansion parameters. These parameters may facilitate coupling of the thermal spreader to a die and heat sink. These parameters may further facilitate the presence of a robust thermal channel that has low thermal resistances allowing thermal energy to be transferred from the die to the heat sink. Methods of manufacturing an integrated circuit (IC) device having such a thermal spreader, as well as systems incorporating the IC device are also disclosed.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous. The term “coupled” may refer to a direct connection, an indirect connection, or an indirect communication.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other.

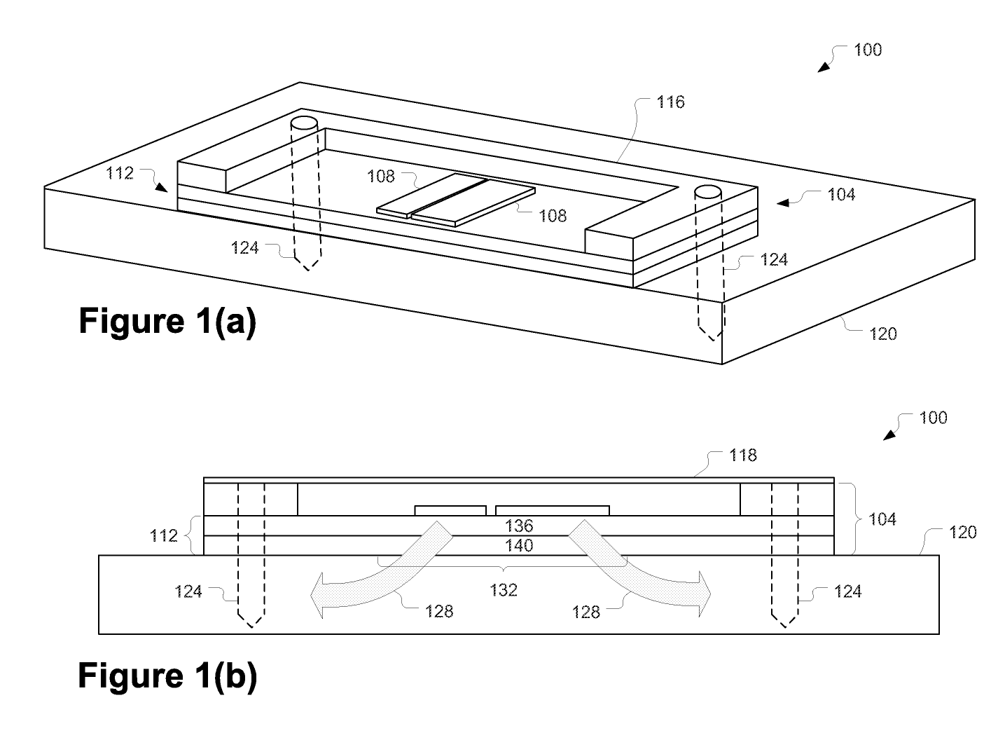

FIGS. 1(a) and (b) respectively illustrate a cross-section perspective view and side view of an integrated circuit (IC) device 100, according to various embodiments. The IC device 100 may include a microelectronic package (hereinafter “package”) 104 that has one or more dies 108 coupled with a thermal spreader 112. The dies 108 may be coupled with a layer 136 of the thermal spreader 112. In some embodiments, the dies 108 may be coupled with a diamond or other tab, with the resulting assembly being coupled with the layer 136.

The layer 136 may also be referred to as “top layer 136,” given the orientation shown in FIG. 1. The dies 108 may be composed of any of a variety of semiconductor materials having integrated circuits fabricated therein. In some embodiments, the dies 108 may be monolithic microwave integrated circuits (MMICs) including, e.g., field effect transistors, and fabricated within a III-V compound semiconductor material such as, but not limited to gallium arsenide (GaAs) or gallium nitride (GaN).

The package 104 may further include a ring 116 that occupies a perimeter of the thermal spreader 112. The ring 116 may provide an attachment mechanism for lid 118 (shown in FIG. 1(b)). The ring 116 may be composed of materials such as, but not limited to, ceramic, Kovar, copper, etc.

The IC device 100 may further include a heat sink 120 coupled with the package 104. More specifically, the heat sink 120 may be coupled with a layer 140 of the thermal spreader 112. The layer 140 may also be referred to as the “bottom layer 140,” given the orientation shown in FIG. 1. The heat sink 120 may be composed of thermally conductive materials such as, but not limited to, copper, aluminum, graphite foam, composites, etc.

The heat sink 120 may be coupled with the package 104 by a plurality of screws 124. In other embodiments, other attachment mechanisms may be used to couple the heat sink 120 with the package 104 such as, but not limited to, clamps, rivets, solder, etc. The screws 124 may be disposed in corners of the package 104. In some embodiments, a thermal interface material (TIM) may be disposed between the thermal spreader 112 and the heat sink 120. The TIM may include, but is not limited to, a thermal grease, a thermally-conductive gel pad, or a shim, e.g., an indium shim.

During operation, heat sourced from the dies 108 may be transferred through the thermal spreader 112 into the heat sink 120 as shown by arrows 128 in FIG. 1(b). Providing low thermal resistances throughout the thermal channel from the dies 108 to the heat sink 120 may facilitate dissipation of large densities of heat energy sourced by operation of the dies 108. When the screws 124 are used to couple the package 104 to the heat sink 120, the corners of the package 104 may be preloaded into the heat sink 120 causing an upward deflection in a central area 132 of the package 104. This upward deflection may result in an air gap between the package 104 and the heat sink 120 disrupting the thermal channel and leading to a high-heat flux area directly under the dies 108.

Various embodiments of the present invention provide the thermal spreader 112 with properties to counteract the noted upward deflection. In particular, in accordance with an embodiment, the thermal spreader 112 is constructed with graduated thermal expansion parameters, e.g., graduated coefficient of thermal expansions (CTEs). As used herein, “graduated thermal expansion parameters” means that the parameters of the thermal spreader 112 gradually increase or decrease from a first major surface, e.g., surface of top layer 136 with which the dies 108 are coupled, to a second major surface, e.g., surface of bottom layer 140 with which the heat sink 120 is coupled.

For example, the thermal spreader 112 may include a layer 136 (also referred to as “top layer 136”) having first thermal expansion parameters, e.g., a first CTE, and a layer 140 (also referred to as “bottom layer 140”) having second thermal expansion parameters, e.g., a second CTE. In some embodiments, the second CTE may be greater than the first CTE. For example, in some embodiments, the first CTE may be within a range of approximately 4-7 parts per million per degree Celsius (ppm/° C.) and the second CTE may be within a range of approximately 14-28 ppm/° C.

When a thermal load is applied to the thermal spreader 112, the bottom layer 140 may tend to expand greater than the top layer 136. This may result in a downward deflection of the central area 132 that counteracts, in part or in full, the upward deflection that results from preloading the corners of the package 104 into the heat sink 120.

The downward deflection of the central area 132 caused by the graduated thermal expansion parameters may increase the pressure between the thermal spreader 112 and the heat sink 120 in the central area 132. This may result in desirably low thermal resistances throughout the thermal channel from the dies 108 to the heat sink 120. This may, in turn, result in lower operating temperatures of the dies 108.

In some embodiments, the increased contact pressure at the central area 132 may allow the use of less TIM or even forgo the use of a TIM altogether. Reducing or eliminating use of a TIM may reduce or eliminate reliability problems associated with the use of TIMs in high power applications.

In some embodiments, the top layer 136 and the bottom layer 140 may each have a thickness in a range of approximately 0.005″-0.015″ and 0.015″-0.050″, respectively. In some embodiments, the relative thicknesses of the layers of the thermal spreader 112 may be adjusted to obtain the desired downward deflection of the central area 132.

In various embodiments, the top layer 136 and the bottom layer 140 may be composed of thermally-conductive materials such as, but not limited to, copper, aluminum, graphite foam, tungsten, molybdenum, composite materials (e.g., copper-tungsten pseudoalloy, aluminum silicon carbide, diamond in copper-silver alloy matrix, beryllium oxide in beryllium matrix, copper moly, etc.).

In some embodiments, the materials and thicknesses for the top layer 136 and bottom layer 140 may be selected so as to provide desired deflection. For example, an embodiment in which a small deflection is desired may have a relatively thick top layer 136 of tungsten, which has a stiffness of approximately three-times that of copper, and a relatively thin bottom layer 140 of copper.

In some embodiments, the CTE of the top layer 136 may be matched to a CTE of the dies 108, while the CTE of the bottom layer 140 may be matched to the CTE of the heat sink 120. Whether one CTE is matched with another may depend on area of contact. As the area increases, the CTEs may need to be closer to one another in order to be considered matched. As used herein, a first CTE may be considered as being matched with a second CTE if it is within 5 ppm/° C. of the second CTE. Matching CTEs between adjacent components may increase the reliability of the coupling between those components.

In some embodiments, it may be desired for the CTE at an interface between two adjacent components, e.g., at a braze joint, to be matched. In some embodiments, the CTEs of the adjacent components/layers may undershoot or overshoot the interface CTE in order to provide the desired interface CTE.

While the thermal spreader 112 is shown with two layers having respective thermal expansion parameters, other embodiments may include one or more intermediate layers between the top layer 136 and the bottom layer 140. The intermediate layers may have respective expansion parameters. In some embodiments, these intermediate layers may facilitate a gradual transition from the thermal expansion parameters of the top layer 136 to the thermal expansion parameters of the bottom layer 140. Providing a gradual transition in the thermal expansion parameters may decrease inter-layer stress that may occur through thermal cycling.

The layers of the thermal spreader 112 may not be distinctly demarcated in all embodiments. For example, layers 136 and 140 may be constructed of the same, or similar, material, yet may have their respective thermal expansion parameters modified with respect to one another through a manufacturing process such as, but not limited to, chemical vapor deposition (CVD), ion implantation, annealing, etc.

While embodiments describe providing the thermal spreader 112 with graduated thermal expansion parameters, other embodiments may additionally/alternatively provide other components with similar graduated parameters. For example, in some embodiments, the heat sink 120 may be provided with graduated thermal expansion parameters, which may be useful in the event another heat sink was attached to a bottom surface of the heat sink 120.

In various embodiments, electrical interconnects may be provided in the thermal spreader 112 and/or heat sink 120. The electrical interconnects may electrically couple dies 108 with one another and/or with one or more electrical components disposed external to the IC device 100, e.g., on a circuit board with which the IC device 100 is coupled.

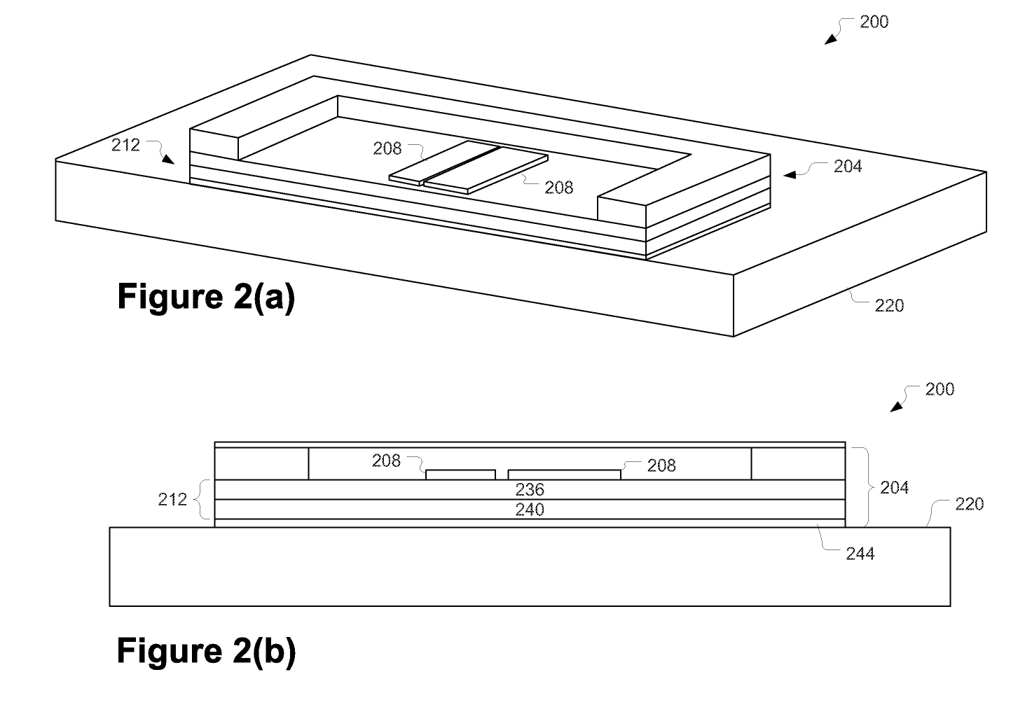

FIGS. 2(a) and (b) respectively illustrate a cross-section perspective view and side view of an IC device 200 according to various embodiments. Similar to IC device 100, the IC device 200 may have a package 204 having a thermal spreader 212 coupled with dies 208 at a first surface and heat sink 220 at a second surface. The thermal spreader 212 may include layers 236 and 240 (also referred to as “top layer 236” and “bottom layer 240,” respectively), having respective thermal expansion parameters similar to that described above.

Unlike IC device 100, the IC device 200 may be coupled with the heat sink 220 by a solder layer 244 rather than screws. Use of the solder layer 244 may be enabled, at least in part, by matching the CTE of bottom layer 240 to CTE of heat sink 220. The solder layer 244 may provide desirable stability and thermal conductivity in the thermal channel between the dies 208 and the heat sink 220.

The solder layer 244 may cover a substantial portion of the bottom surface of the package 204. In some embodiments, the solder layer 244 may cover the entire bottom surface of the package 204.

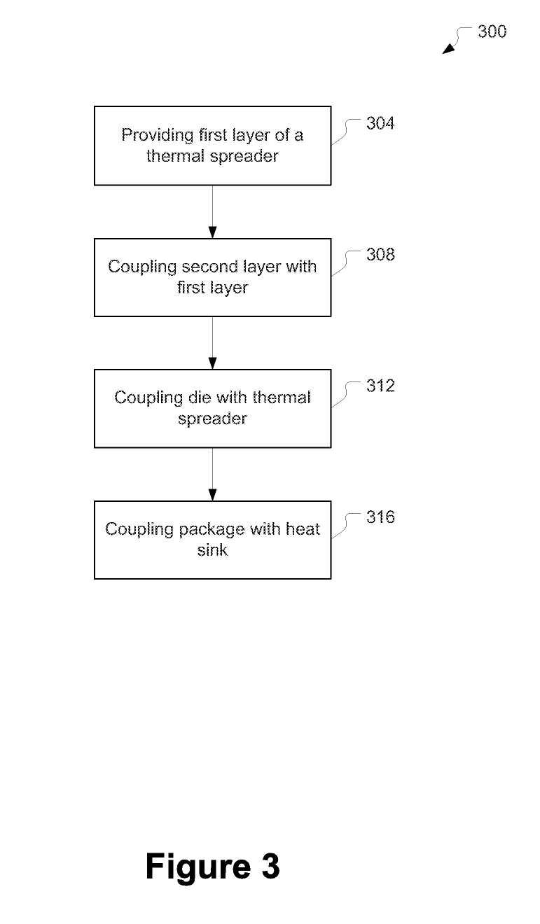

FIG. 3 is a flowchart depicting a manufacturing operation 300 in accordance with some embodiments. The manufacturing operation 300 may be used to construct IC device 100 or 200.

The manufacturing operation 300 may include, at block 304, providing a first layer of a thermal spreader. The first layer may be, e.g., bottom layer 140 or 240. The providing of the first layer may include, in some embodiments, varying thermal expansion properties of the material of the first layer. This may be done through operations such as, but not limited to, CVD, ion implantation, annealing, etc.

The manufacturing operation 300 may further include, at block 308, coupling a second layer with the first layer to form a thermal spreader. The second layer may be, e.g., top layer 136 or 236. While the presently-described embodiment refers to the first layer as the bottom layer and the second layer as the top layer, other embodiments may have the first layer as the top layer and the second layer as the bottom layer.

The second layer may be coupled with the first layer by being formed directly on the first layer through a deposition process such as, but not limited to, CVD, physical vapor deposition (PVD), and/or atomic layer deposition (ALD). In other embodiments, the second layer may be coupled with the first layer by attaching the second layer to the first layer. The second layer may be attached to the first layer by being brazed together with high-strength, high-temperature filler material, being rolled on the first layer and laminated under high temperature and pressure, etc.

In various embodiments, the thermal expansion properties of the material of the second layer may be varied through operations such as, but not limited to, ion implantation, annealing, CVD, etc.

In various embodiments, one or more intermediate layers may be formed between the first layer and the second layer. In this event, adjacent layers may be coupled with one another in a process similar to that described above.

The manufacturing operation 300 may further include, at block 312, coupling a die with the thermal spreader. The die and thermal spreader may be referred to as package, as described above. The die may be coupled with the thermal spreader in a manner to provide both mechanical and electrical coupling. In some embodiments, a coupling mechanism may serve both mechanical and electrical coupling functions. In other embodiments, some coupling mechanisms may serve mechanical coupling functions while other coupling mechanisms may serve electrical coupling functions.

The manufacturing operation 300 may further include, at block 316, coupling package with a heat sink. In embodiment in which the manufacturing operation 300 is used to construct IC device 100, the coupling at block 316 may include coupling the package with the heat sink using a plurality of screws. In an embodiment in which the manufacturing operation 300 is used to construct IC device 200, the coupling at block 316 may include coupling the package with the heat sink using a solder layer. In other embodiments, other types of coupling arrangements may be used.

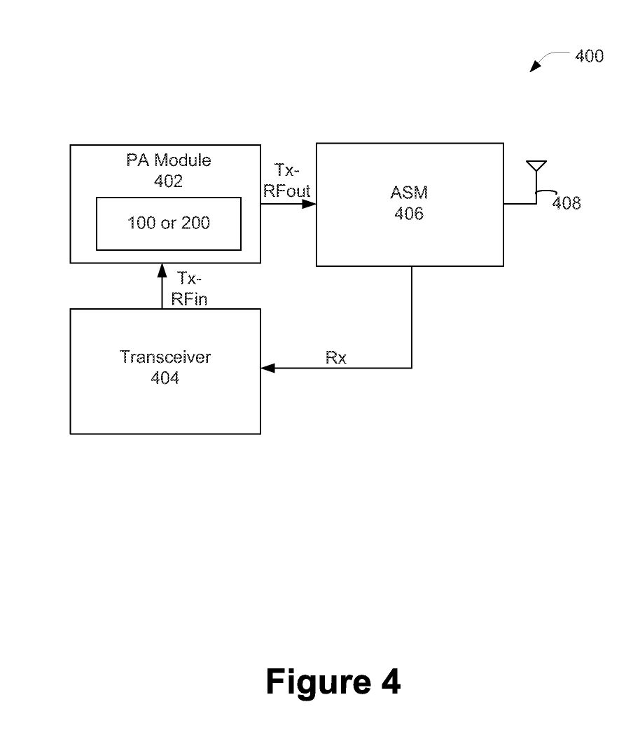

Embodiments of an IC device (e.g., the IC device 100 or 200) described herein, and apparatuses including such an IC device may be incorporated into various other apparatuses and systems. A block diagram of an example system 400 is illustrated in FIG. 4. As illustrated, the system 400 includes a power amplifier (PA) module 402, which may be a radio frequency (RF) PA module in some embodiments. The system 400 may include a transceiver 404 coupled with the PA module 402 as illustrated. The PA module 402 may include an IC device (e.g., the IC device 100 or 200) to perform any of a variety of operations such as amplification, switching, mixing, etc. In various embodiments, an IC device (e.g., IC device 100 or 200) may additionally/alternatively be included in the transceiver 404 to provide, e.g., up-converting.

The PA module 402 may receive an RF input signal, RFin, from the transceiver 404. The PA module 402 may amplify the RF input signal, RFin, to provide the RF output signal, RFout. The RF input signal, RFin, and the RF output signal, RFout, may both be part of a transmit chain, respectively noted by Tx-RFin and Tx-RFout in FIG. 4.

The amplified RF output signal, RFout, may be provided to an antenna switch module (ASM) 406, which effectuates an over-the-air (OTA) transmission of the RF output signal, RFout, via an antenna structure 408. The ASM 406 may also receive RF signals via the antenna structure 408 and couple the received RF signals, Rx, to the transceiver 404 along a receive chain.

In various embodiments, the antenna structure 408 may include one or more directional and/or omnidirectional antennas, including, e.g., a dipole antenna, a monopole antenna, a patch antenna, a loop antenna, a microstrip antenna or any other type of antenna suitable for OTA transmission/reception of RF signals.

The system 400 may be any system including power amplification. In various embodiments, the inclusion of IC device 100 or 200 in the system 400 may be particularly useful when the system 400 is used for power amplification at high RF power and frequency. For example, the system 400 may be suitable for any one or more of terrestrial and satellite communications, radar systems, and possibly in various industrial and medical applications. More specifically, in various embodiments, the system 400 may be a selected one of a radar device, a satellite communication device, a mobile computing device (e.g., a phone, a tablet, a laptop, etc.), a base station, a broadcast radio, or a television amplifier system.

Although certain embodiments have been illustrated and described herein for purposes of description, a wide variety of alternate and/or equivalent embodiments or implementations calculated to achieve the same purposes may be substituted for the embodiments shown and described without departing from the scope of the present disclosure. This application is intended to cover any adaptations or variations of the embodiments discussed herein. Therefore, it is manifestly intended that embodiments described herein be limited only by the claims and the equivalents thereof.

What is claimed is:

1. An apparatus comprising:
a die;
a thermal spreader having a first layer with a first coefficient of thermal expansion (CTE) and a second layer with a second CTE that is greater than the first CTE, the die coupled with the first layer of the thermal spreader; and
a heat sink coupled with the second layer of the thermal spreader.

2. The apparatus of claim 1, wherein the thermal spreader further comprises a third layer, disposed between the first and second layers, the third layer having a third CTE that is between the first and second CTEs.

3. The apparatus of claim 1, wherein the electronic component has a third CTE and the first CTE is matched with the third CTE.

4. The apparatus of claim 1, wherein the heat sink has a third CTE and the second CTE is matched with the third CTE.

5. The apparatus of claim 1, wherein the thermal spreader is coupled with the heat sink by a plurality of screws.

6. The apparatus of claim 5, wherein the thermal spreader is configured to exhibit a deflection upon application of a thermal load that counteracts a deflection caused by coupling of the thermal spreader with the heat sink by the plurality of screws.

7. The apparatus of claim 1, wherein the thermal spreader is coupled with the heat sink by a solder layer.

8. The apparatus of claim 7, wherein the first CTE is matched with a third CTE of the die and the second CTE is matched with a fourth CTE of the heat sink.

9. The apparatus of claim 1, wherein the first CTE is within a range of approximately 4-7 parts per million per degree Celsius (ppm/° C.) and the second CTE is within a range of approximately 14-28 ppm/° C.

10. A method comprising:
providing a first layer of a thermal spreader, the first layer having a first coefficient of thermal expansion (CTE);
coupling a second layer of the thermal spreader with the first layer, the second layer having a second CTE that is less than the first CTE;
coupling a die with the second layer; and
coupling a heat sink with the first layer.

11. The method of claim 10, wherein coupling the second layer with the first layer comprises:
forming the second layer on the first layer.

12. The method of claim 11, wherein forming the second layer on the first layer comprises:
depositing the second layer on the first layer by a deposition process.

13. The method of claim 10, wherein coupling the second layer with the first layer comprises:
attaching the second layer with the first layer.

14. The method of claim 13, wherein attaching the second layer with the first layer comprises:
rolling the second layer on the first layer; and
laminating the second layer with the first layer.

15. The method of claim 13, wherein attaching the second layer with the first layer comprises:
brazing the second layer with the first layer using a filler material.

16. The method of claim 10, further comprising:
coupling one or more intermediate layers between the first and second layers.

17. The method of claim 10, wherein coupling the heat sink with the first layer comprises:
coupling the heat sink with a package that includes the thermal spreader with a plurality of screws.

18. The method of claim 10, wherein coupling the heat sink with the first layer comprises:
soldering the heat sink with the first layer.

19. A system comprising:
a transceiver configured to provide a radio frequency (RF) signal;
a power amplification module configured to receive the RF signal from the transceiver and amplify the RF signal for an over-the-air transmission; and
an integrated circuit (IC) device, disposed in the transceiver or in the PA module, the IC device including a thermal spreader coupled with a die and a heat sink, the thermal spreader including graduated thermal expansion parameters.

20. The system of claim 19, wherein the thermal spreader includes:
a first layer, coupled with the die, having a first coefficient of thermal expansion (CTE); and
a second layer, coupled with the heat sink, having a second CTE that is greater than the first CTE.
